(19) United States
(12) Patent Application Publication
(10) Pub. No.: US 2008/0115331 A1
(43) Pub. Date: May 22, 2008

(54) DEVICE FOR PARTICLE PRODUCTION

(76) Inventors: Hans-Rudolf HIMMEN, Haimhausen (DE); Hans-Jurgen Reinhardt, Kaufbeuren (DE)

Correspondence Address: THE BOC GROUP, INC., 575 MOUNTAIN AVENUE, MURRAY HILL, NJ, 07974-2064, US

(21) Appl. No.: 11/936,977

(22) Filed: Nov. 8, 2007

(30) Foreign Application Priority Data
Nov. 14, 2006 (DE) 10 2006 053 632.0
Nov. 28, 2006 (DE) 10 2006 056 119.8
Dec. 12, 2006 (EP) 06025716.9

(51) Int. Cl. C30B 7/08

(52) U.S. Cl. 23/295 R; 422/245.1

(57) ABSTRACT

The present invention relates to a device and a method for producing granulated material by melt crystallization having a nozzle prechamber for receiving a melt, having nozzles for producing droplets of the melt, and having a cooling pipe for cooling the droplets, means being provided to prevent undercooling of the nozzles.

### CROSS REFERENCE TO RELATED APPLICATIONS

This application claims priority from German Patent Application Serial No. 102006053632.0, filed Nov. 14, 2006; European Patent Application Serial No. 06025716.9, filed Dec. 12, 2006; and German Patent Application Serial No. 102006056119.8.

### BACKGROUND OF THE INVENTION

The present invention relates to a device for producing granulated material by melt crystallization having a nozzle prechamber for receiving a melt, having nozzles for producing droplets of the melt, and having a cooling pipe for cooling the droplets. Furthermore, the present invention relates to a method for producing granulated material by melt crystallization, a melt being conducted through nozzles and droplets of the melt being produced, which are subsequently crystallized.

In the melt crystallization method, which is also referred to as prilling, a liquid melt is fed to the head of a cooling pipe and divided into uniform droplets. These fall downward in a solidification pipe and are brought into contact with a cryogenic gas flow. The droplets solidify into beads having a diameter preferably in the range from 0.4 to 2 mm.

The essential components of the droplet formation system are the nozzles, which are located at the top end of a vertical cooling pipe. The melt located in the nozzle prechamber enters through the nozzles into the cooling pipe situated underneath and is divided into uniform droplets.

A nozzle plate having holes into which individual nozzles are screwed is usually provided for this purpose. The nozzle plate may also solely comprise a plate having outlet openings of suitable size, however. The hot melt is located on the top side of the nozzle plate, while the bottom side of the nozzle plate adjoins the cooling pipe having colder atmosphere. For the predominantly relevant case, in which separate nozzles are screwed into the nozzle plate, the outlet openings of the nozzles have a significant distance to the nozzle plate. This means that the outlet openings of the nozzles are subjected to the cold atmosphere in the cooling pipe and are only inadequately heated by the heated melt.

The danger thus results that the nozzles will clog if the temperature of the melt is not far enough above the melting temperature of the material to be made into droplets. Vice versa, the temperature of the melt is to be kept as low as possible to minimize the cooling effort for the subsequent crystallization of the droplets.

### BRIEF SUMMARY OF THE INVENTION

The object of the present invention is therefore to disclose a device and a method of the type cited at the beginning, which reliably prevent clogging of the nozzles even with a small temperature difference between the temperature of the melt and its melting temperature.

This object is achieved by a device for producing granulated material by melt crystallization having a nozzle prechamber for receiving a melt, having nozzles for producing droplets of the melt, and having a cooling pipe for cooling the droplets, which is distinguished in that means are provided to prevent undercooling of the nozzles.

The method according to the present invention for producing granulated material by melt crystallization, a melt being conducted through nozzles and droplets of the melt being produced, which are subsequently crystallized, is characterized in that undercooling of the nozzles to a temperature at which the droplets crystallize in the nozzle is prevented.

According to the present invention, undercooling of the nozzles, i.e., cooling down to a temperature at which the droplets would already crystallize in the nozzles, is prevented. This may be achieved in that suitable means are provided for heating the nozzles and/or the nozzles are thermally shielded from the cold atmosphere of the cooling pipe lying underneath. In other words: either heat may be actively fed to the nozzles or the heat dissipation to the cold atmosphere may be reduced.

It is thus possible to keep the melt in the nozzle prechamber at a temperature which is only slightly above the melting temperature of the material to be dripped. The heated melt does not cool down below its solidification temperature in the nozzles and thus does not clog the nozzles. The term “nozzles” is to be understood here to mean all types of elements or openings which are capable of dividing the melt into individual droplets.

In a preferred embodiment, the nozzles from which the heated melt exits in droplet form are heated. In another preferred embodiment, the nozzles are situated in nozzle channels, which form an outlet chamber open to the cooling pipe downstream from the outlet openings of the nozzles. The exit of the droplets from the nozzles does not occur directly into the cold atmosphere of the cooling pipe, but rather into the outlet chamber situated before the nozzle openings. The outlet chamber is open in the direction of the cooling pipe, so that the droplets may enter the cooling pipe unobstructed. However, a somewhat warmer buffer atmosphere is implemented in the outlet chamber in relation to the atmosphere in the cooling pipe, which prevents the outlet openings of the nozzles from being cooled so much that the melt solidifies therein and clogs the nozzles.

In addition to the means for heating the nozzles, separate means are advantageously provided for heating the melt located in the nozzle prechamber. The melt in the nozzle prechamber is advantageously heated in indirect heat exchange with a liquid heat transfer medium, in particular thermal oil. The walls of the nozzle prechamber may be implemented as a double mantle for this purpose, for example, in whose intermediate spaces the terminal transfer medium flows and indirectly heats the melt or keeps it at the desired temperature. The melt may thus be kept in a controlled way at a temperature which has a sufficient distance to the melting point of the material to be dripped.

If the melt is heated independently of the local heating of the nozzles, this has the advantage that the temperature of the nozzles may be set in wide ranges without the melt being overheated, for example.

In a preferred design of the present invention, the means for heating the nozzles have an electrical heating element. The electrical heating element may be implemented as a flexible heating strip heated by resistance heating, for example, which is wound or braided in one or more layers around the nozzles.

Instead of an electrical heating element, heating the nozzles using a heat transfer fluid has also proven itself. The liquid heat transfer medium preferably washes around the nozzles and brings them to the desired temperature.

The heating of the nozzles and the heating of the melt may occur via separate heating devices or via a shared heating device. If the melt is heated via indirect heat exchange with a heat transfer medium, such as a thermal oil, a part of the heat transfer medium may be diverted and led to the nozzles, for example, to also wash around them.

The production of the droplets is advantageously supported in that a controlled overpressure is generated in the nozzle prechamber. This is performed, for example, by introducing an inert gas, in particular gaseous nitrogen, into the head space of the nozzle prechamber or by hydrostatic pressure, which may be set via the supply level of the melt in the nozzle prechamber.

It has also been proven to be favorable to set the melt in the nozzle prechamber into oscillations, so that local pressure differences are caused in the melt and the melt is conveyed through the nozzles.

The droplets exiting from the nozzles are advantageously cooled and pre-solidified in the adjoining cooling pipe in direct heat exchange with cold gaseous nitrogen. Total crystallization or complete hardening of the droplets is not necessarily achieved in the cooling pipe. The final solidification of the droplets preferably occurs in a bath of liquid nitrogen. The droplets falling through the cooling pipe and pre-solidified into granulated material are completely crystallized in the nitrogen bath and transported out of the nitrogen bath using a discharge system. The gaseous nitrogen arising during operation of the prilling facility is preferably used for inertizing, in particular for inertizing the packing drum.

The present invention is particularly suitable for use with melts having a temperature between 40° C. and 300° C. The melts are typically materials from fine and special chemistry, such as unsaturated fatty acids as intermediate products for the cosmetic industry or pigment particles for inkjet printer inks. The melts are transferred into the liquid state by heating.

The present invention has numerous advantages in relation to the known devices and/or methods for prilling:

According to the present invention, the melt is only heated just above the melting point of the material, by which heating energy is saved. In addition, the cooling energy, for example, in the form of cryogenic nitrogen, required for the subsequent hardening of the produced droplets is reduced. Moreover, more sensitive melts which may be damaged by heating may also be processed without problems.

Clogging of the nozzles by prematurely solidified melt is prevented, because of which the prilling process must only be stopped in the event of a product change. The complex cleaning of the nozzles otherwise required in the event of nozzle clogs is dispensed with. A higher productivity of the facility is thus achieved.

The device according to the present invention is designed simply and robustly, is easily controllable, and may be used universally. Depending on the external conditions, the dimensions of the facility, its diameter and height, as well as the number, size, and configuration of the nozzles may be varied easily.

The present invention and further details of the present invention are explained in greater detail in the following on the basis of exemplary embodiments illustrated in the drawings.

### BRIEF DESCRIPTION OF THE DRAWINGS

FIG. 1 shows a prilling facility according to the prior art.

FIG. 2 shows a prilling facility according to the present invention.

FIG. 3 shows a variant of the prilling facility according to the present invention.

FIG. 4 shows a further variant of the present invention.

FIG. 5 shows another alternative embodiment of the present invention.

### DETAILED DESCRIPTION OF THE INVENTION

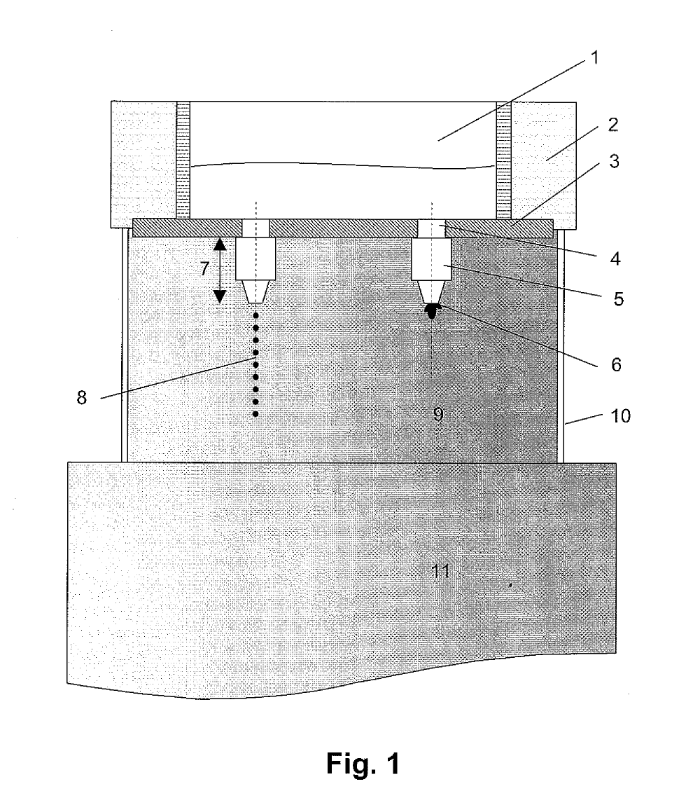

FIG. 1 shows the droplet formation system of a so-called prilling facility for producing granulated material by melt crystallization, as is known from the prior art. A nozzle prechamber 1, into which a molten material is introduced, is located at the head of the device shown. The nozzle prechamber 1 is kept at a temperature above the melting temperature of the material using a hot thermal oil, which is located in an annular channel 2 enclosing the nozzle chamber 1.

The floor 3 of the nozzle prechamber 1 has multiple holes 4, into which nozzles 5 are screwed from below. The nozzle outlet openings 6 of the nozzles 5 have a distance 7 from the floor 3 of the nozzle prechamber 1 which is a function of the length of the nozzles 5.

In normal operation of the facility, the molten material is conducted out of the nozzle prechamber 1 by controlled overpressure into the nozzles 5, which divide the continuous melt flow into fine droplets 8. The droplets 8 fall through a viewing section 9, which is provided with viewing windows 10. The droplet formation process may be observed and monitored through the viewing windows 10.

A cooling pipe 11, in which the droplets come into direct contact with an atmosphere made of cold gaseous nitrogen, are cooled down, and crystallize into the desired granulated material, adjoins the viewing section 9.

In this known device, the relatively large distance 7 between the nozzle outlet openings 6, which are subjected to the cold nitrogen atmosphere, and the floor 3 of the nozzle prechamber 1, may result in problems. The nozzles 5 are strongly cooled by the surrounding cold atmosphere and, vice versa, only slightly heated by the hot melt bath, so that the molten droplets sometimes cooled down so much in the nozzles 5 that they at least partially crystallize and clog the nozzle outlet openings 6.

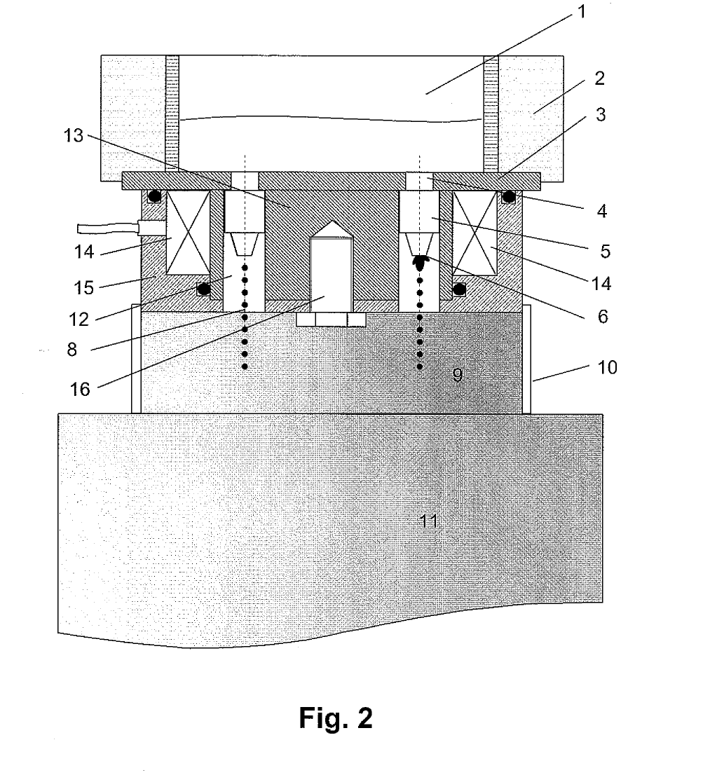

A facility 1 for prilling according to the present invention is schematically illustrated in FIG. 2. The nozzle prechamber 1 having the surrounding annular channel 2 for receiving a hot thermal oil is constructed like the facility shown in FIG. 1. The floor 3 of the nozzle prechamber 1 also has holes 4 having nozzles 5 which may be screwed in. The holes 4 having the nozzles 5 are preferably situated in a circle.

However, the nozzles 5 having the nozzle outlet openings 6 do not project directly into the cold atmosphere of the viewing section 9 located underneath and/or the cooling pipe 11, but rather are located in nozzle channels 12. For this purpose, a nozzle receptacle element 13, which has good thermal conductivity and is typically metallic, is provided, which has a cylindrical shape in the embodiment shown in FIG. 2. Nozzle channels 12, whose configuration and diameter corresponds to the configuration and size of the nozzles 5, are drilled into the nozzle receptacle element 13 in the direction of the cylinder axis. The height of the nozzle receptacle element 13 is selected in such a way that it exceeds the distance 7 of the nozzle outlet openings of the nozzles 5 from the floor 3.

The nozzle receptacle element 13 forms a unit with the floor 3 of the nozzle prechamber 1, so that the nozzles 5 are received in the nozzle channels 12. In this way, the nozzles 5 are not directly subjected to the cold atmosphere of the cooling pipe 11 and/or the viewing section 9. In addition, a part of the thermal energy of the melt bath is conducted via the nozzle receptacle element 13 to the nozzles 5. Depending on the length of the nozzle channels 12, the cooling of the nozzles 5 may thus be reduced enough that the melt no longer solidifies in the nozzles 5 and blocks them.

In addition, a hollow cylindrical heating element 14, which encloses the nozzle receptacle element 13, is also provided in the embodiment shown in FIG. 2. The heating element 14 may be electrically heated or may be charged with hot thermal oil or another heat transfer medium, similarly to the annular channel 2, for example. A heating element holder 15, which preferably has the poorest possible heat conduction, is fastened via a screw connection 16 to the nozzle receptacle body 13 to fasten and insulate the heating element 14.

Using the heating element 14, the temperature of the area around the nozzles 5 and around the nozzle channels 12 may be set in a broad temperature range. The heating element 14 preferably operates independently of the type and/or the degree of the heating of the melt in the nozzle prechamber 1. The temperature of the nozzles 5 is selected in such a way that they do not cool too strongly under the influence of the cold atmosphere in the cooling pipe 11 and clogging of the nozzle outlet openings 6 by solidifying melt is prevented.

The viewing section 9, which is provided in this case with an all-around viewing window 10, made of Plexiglas, for example, and which allows unrestricted observation of the droplet formation process from all sides, is provided below the heating element 14.

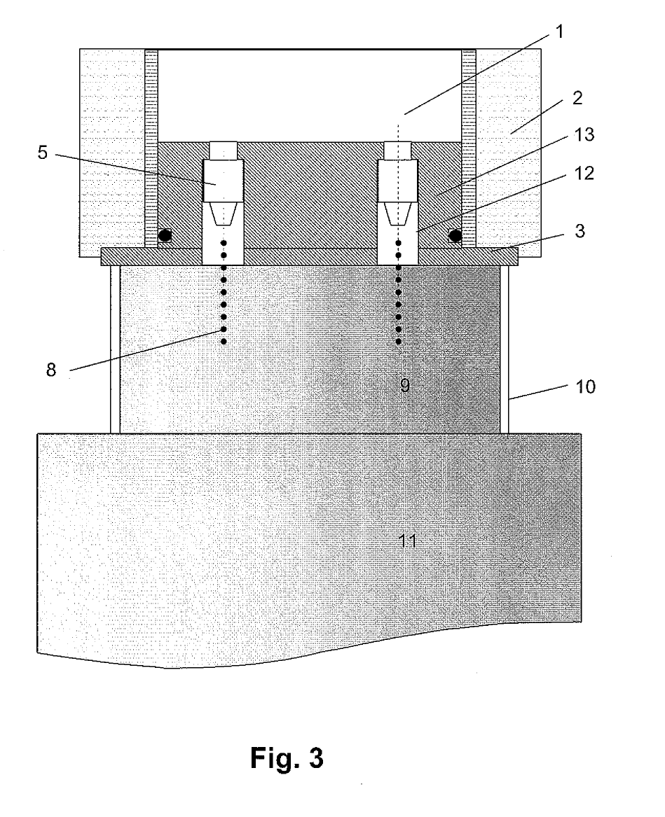

FIG. 3 shows a further design of the present invention, in which the heating of the nozzles 5 is performed using the same heater as the heating of the melt located in the nozzle prechamber 1. A nozzle receptacle element 13, which is provided with nozzle channels 12 for receiving the nozzles 5, is also provided in the embodiment shown in FIG. 3. The nozzle receptacle element 13 is displaced into the nozzle prechamber 1 in this case. The annular channel 2 having the heat transfer medium, such as a hot thermal oil, not only encloses the nozzle prechamber 1, but rather also the nozzle receptacle body 13. In this way, the nozzle receptacle body 13, which comprises a material having good thermal conductivity and relays the heat to the nozzles 5, is heated by the heat transfer medium located in the annular channel 2.

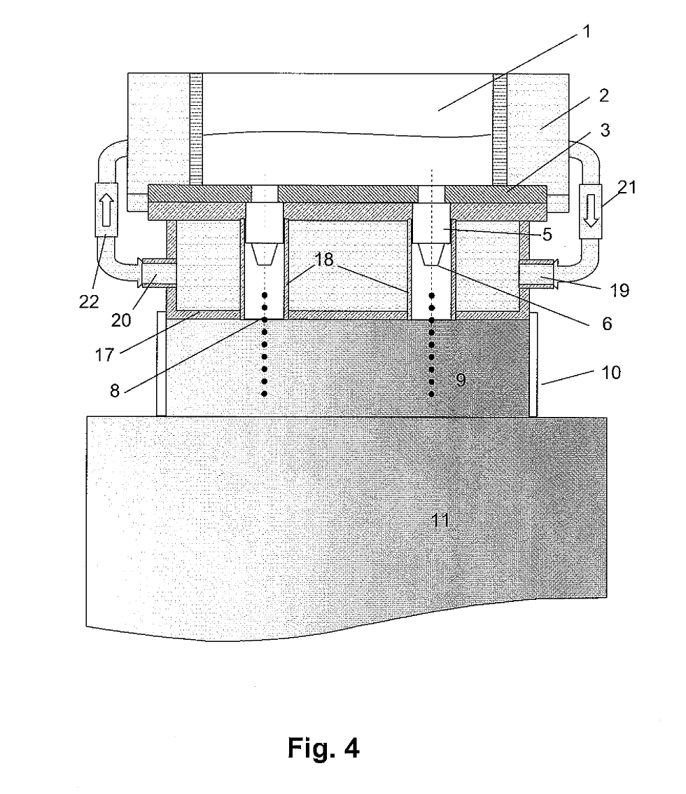

A further preferred design of the present invention is shown in FIG. 4. The nozzle receptacle element 17 is implemented in this case as a hollow body. The nozzle channels are formed by sleeves 18 which project into the hollow nozzle receptacle element 17. The nozzle receptacle element 17 has a supply 19 and a drain line 20 a heat transfer medium, which flows through the interior of the nozzle receptacle element 17 and washes around the sleeves 18. As shown in FIG. 4, the same heating medium is used for heating the melt in the nozzle prechamber 1 and heating the nozzle receptacle element 17. For this purpose, the heating medium is moved via flexible connection lines 21, 22 in a loop between the annular channel 2 and the nozzle receptacle body 17.

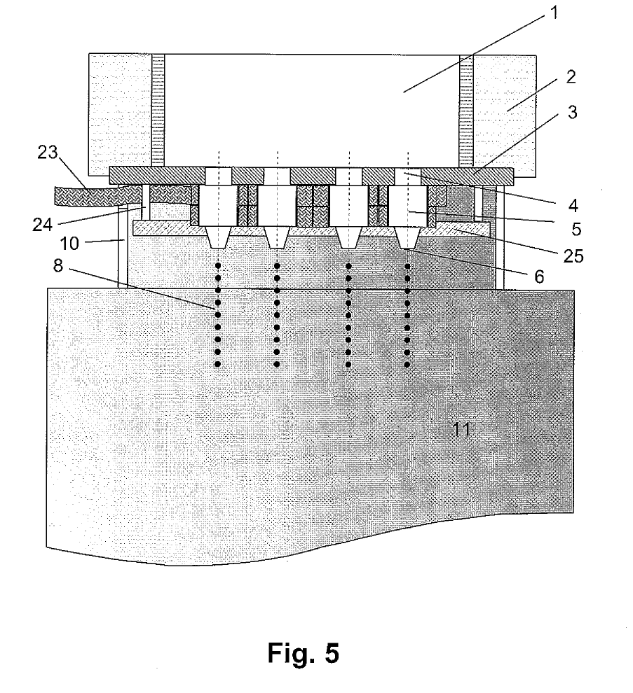

FIG. 5 shows a further alternative for heating the nozzles 5. The heating element is implemented as a flexible strip, which is wound directly in one, two, or more layers around the nozzles 5. A plate 25 is fastened on the floor of the nozzle prechamber 1 via spacers or webs 24 to fix the strip 23.

What we claim is:

1. A device for producing granulated material by melt crystallization having a nozzle prechamber for receiving a melt, having nozzles for producing droplets of the melt and having a cooling pipe for cooling the droplets, characterized in that means are provided to prevent undercooling of the nozzles.

2. The device according to claim 1, characterized in that the means are implemented as means for heating the nozzles.

3. The device according to claim 1, characterized in that the nozzles are situated in nozzle channels, which form an outlet chamber open to the cooling pipe downstream from the outlet openings of the nozzles.

4. The device according to claim 1, characterized in that separate means are provided for heating the melt located in the nozzle chamber.

5. The device according to claim 1, characterized in that the means for heating the nozzles have an electrical heating element.

6. The device according to claim 1, characterized in that the means for heating the nozzles are also used for heating the melt in the nozzle prechamber.

7. The device according to claim 1, characterized in that the means for heating the nozzles comprise a heat transfer fluid, which washes around the nozzles.

8. The device according to claim 1, characterized in that means are provided for generating an overpressure in the nozzle prechamber.

9. The device according to claim 1, characterized in that means are provided for producing an oscillation in the melt located in the nozzle prechamber.

10. A method for producing granulated material by melt crystallization, a melt being conducted through nozzles and droplets of the melt being produced, which are subsequently crystallized, characterized in that undercooling of the nozzles to a temperature at which the droplets crystallize in the nozzles is prevented.

11. The method according to claim 10, characterized in that the melt is transferred into the liquid phase by heating to a temperature between 40° C. and 300° C. and belongs to the field of fine and special chemistry.
